(19) United States
(12) Patent Application Publication
(10) Pub. No.: US 2009/0057640 A1
(43) Pub. Date: Mar. 5, 2009

(54) PHASE-CHANGE MEMORY ELEMENT

(75) Inventors: Yung-Fa Lin, Hsinchu City (TW); Yen-Wen Wang, Taipei (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/964,496

(22) Filed: Dec. 26, 2007

(30) Foreign Application Priority Data
Sep. 4, 2007 (TW) TW96132871

(51) Int. Cl. H01L 47/00

(52) U.S. Cl. 257/3; 438/95; 257/E47.005; 257/E47.001

(57) ABSTRACT

A phase-change memory element and fabrication method thereof is provided. The phase-change memory element comprises an electrode. A first dielectric layer is formed on the substrate. An opening passes through the first dielectric layer exposing the electrode. A heater with an extended part is formed in the opening, wherein the extended part protrudes the opening. A second dielectric layer surrounds the extended part of the heater exposing the top surface of the extended part. A phase-changed material layer is formed on the second dielectric layer to directly contact the top of the extended part.

### BACKGROUND OF THE INVENTION

1. Field of the Invention

The invention relates to a memory element, and more particularly to a phase-change memory element and method for fabricating the same.

2. Description of the Related Art

Electronic devices use different types of memories, such as DRAMs, SRAMs and flash memories or combinations based on application requirements, operating speed, memory size and cost considerations of the equipment. Current developments in the memory technology field include FeRAMs, MRAMs and phase-change memories. Among these alternative memories, phase-change memories are most likely to be mass manufactured in the near future.

Phase-change memories are targeted for applications currently utilizing flash non-volatile memory. Such applications are typically mobile devices which require low power consumption, and hence, minimal programming currents. A phase-change memory cell is designed with several goals in mind: low programming current, higher reliability (including electromigration risk), smaller cell size, and faster phase transformation speed. These requirements often set contradictory requirements on feature size, but a careful choice and arrangement of materials used for the components can often widen tolerance for acceptable requirements.

To reduce the programming current, the most straightforward way is to shrink the heating area. A benefit of this strategy is simultaneous reduction of cell size. Assuming a fixed required current density, the current will shrink in proportion to the area. In reality, however, cooling becomes significant for smaller structures, and heat loss to the surrounding environment becomes more important due to increasing surface/volume ratio. As a result, the required current density must increase as heating area is reduced. This poses an electromigration concern for reliability. Hence, it is important to use materials in the cell which do not pose an electromigration concern. It is also important to improve the heating efficiency, by increasing heating flux in the active programming region while reducing heat loss to the surrounding environment.

U.S. Pat. No. 6,750,079 discloses a method for fabricating a phase-change memory element 10, as shown in FIG. 1. First, a dielectric layer 14 with a perpendicular sidewall is formed on a substrate 12. Next, a metal layer is conformally formed on the dielectric layer 14 and substrate 12. Next, the metal layer is subjected to an anisotropic etching process to form a metal spacer 16 with a smaller top surface. Next, a dielectric layer 18 is formed to cover the sidewalls of the metal spacer 16. Finally, a phase-change layer 20, an electrode 22 and a protective layer 24 are subsequently formed on the substrate. The aforementioned structure, however, is apt to result in a short circuit 30, as shown in FIG. 2,

Therefore, it is necessary to develop a phase-change memory which mitigates the previously described problems.

### BRIEF SUMMARY OF THE INVENTION

A phase-change memory element and fabrication method thereof are provided. The method for fabricating the phase-change memory elements comprises the following steps: Forming a first dielectric layer with an opening on an electrode; Forming a heater within the opening to contact with the electrode, wherein the top surface of the heater is higher than that of the first dielectric layer, defining an extended part of the heater with a first width; Subjecting the first dielectric layer and the heater to an etching process to obtain an etched extended part of the heater, wherein the etched extended part has a second width less than the first width; Forming a second dielectric layer covering the etched extended part of the heater; Subjecting the second dielectric layer to a planarization process, exposing the extended part of the heater; and forming a phase-change material layer on the second dielectric layer and directly in contact with the heater.

According an embodiment of the invention, the phase-change memory element comprises an electrode; a first dielectric layer formed on the electrode; an opening passing through the first dielectric layer, exposing the electrode; a heater formed in the opening to contact to the electrode, wherein the heater has an extended part outside of the opening; a second dielectric layer surrounding the heater to expose the top surface of the extended part of the heater; and a phase-change material layer formed on the second dielectric layer to directly contact to the top surface of the extended part of the heater.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1 and 2 are cross sections of a conventional phase-change memory element.

FIGS. 3a-3h are cross sections of a method for fabricating a phase-change memory element according to an embodiment of the invention.

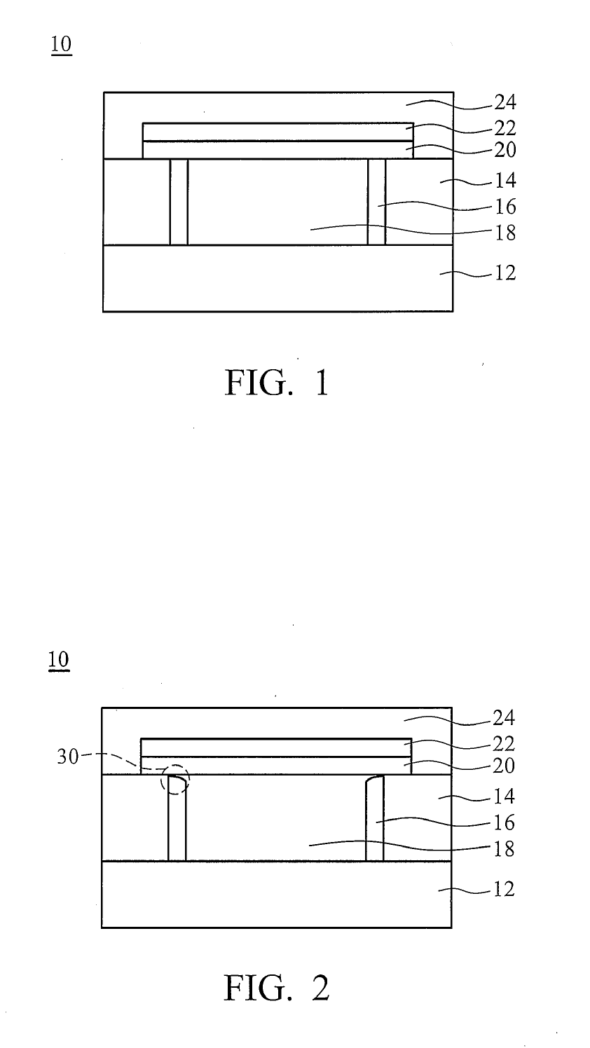

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

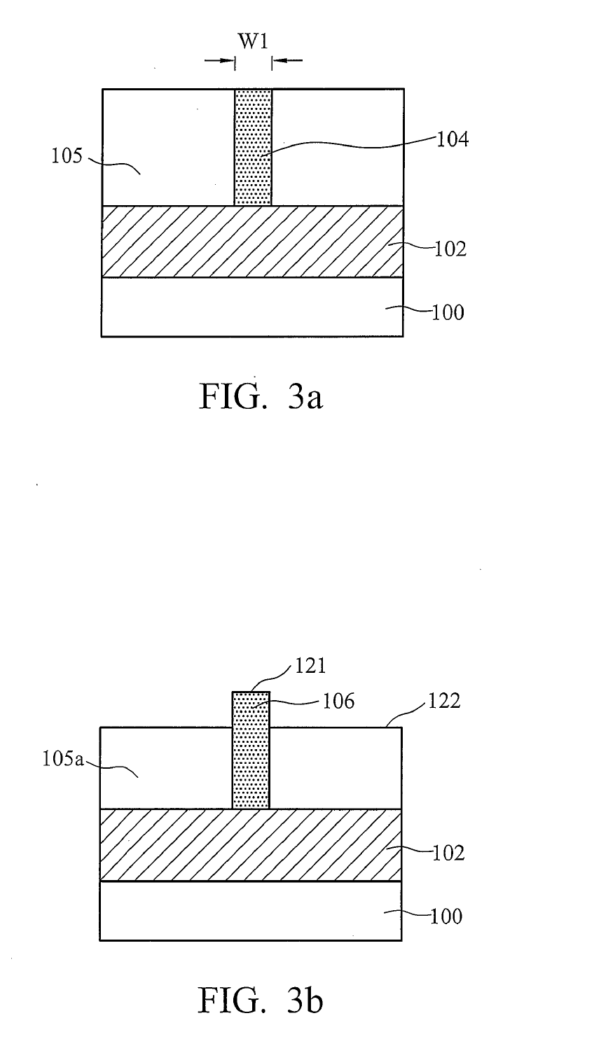

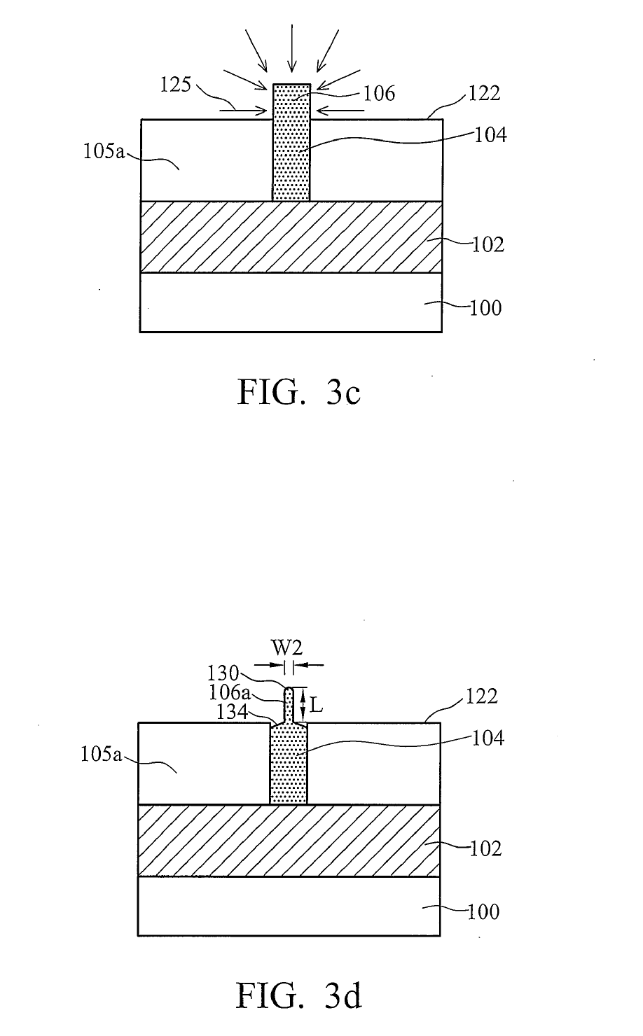

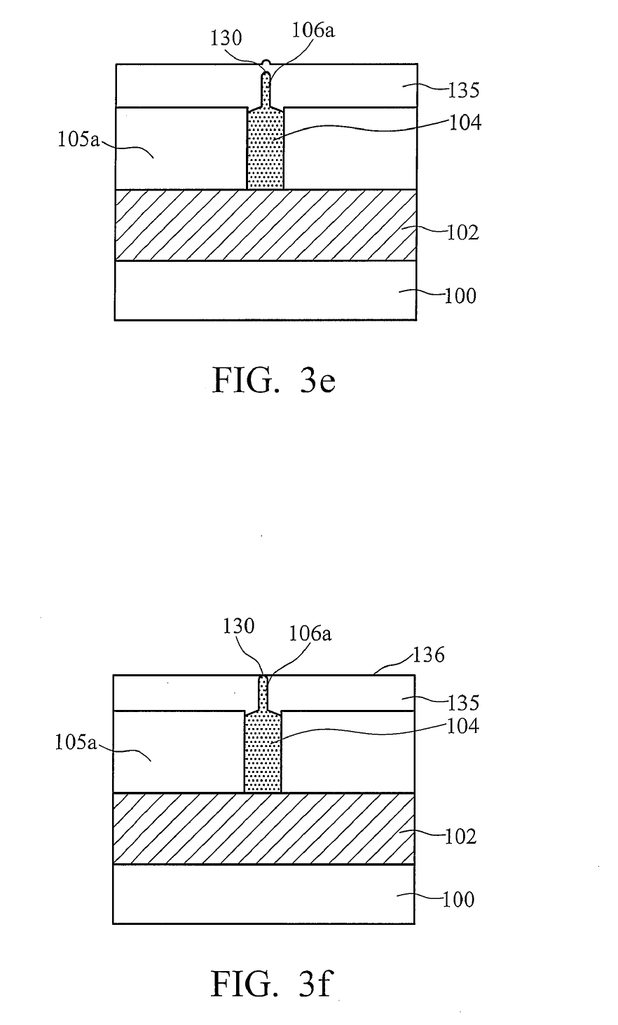

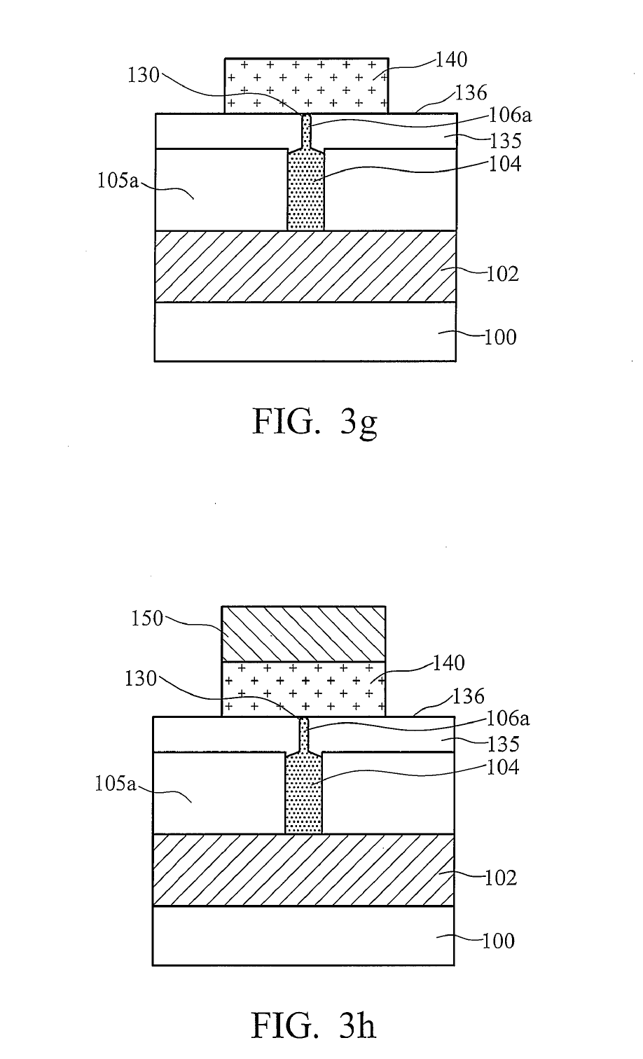

First, referring to FIG. 3a, a substrate 100 is provided and a bottom electrode 102 is formed on the substrate 100. Next, a heater 104 is formed on the bottom electrode 102. Next, a dielectric layer 105 is formed to surround the heater 104. It should be noted that the top surface of the dielectric layer 105 is coplanar with the top surface of the heater 104. The heater 104 can be a pillar-shaped heater.

Particularly, the substrate 100 can be a substrate employed in a semiconductor process, such as a silicon substrate. The substrate 100 can be a substrate comprising a complementary metal oxide semiconductor (CMOS) circuit, isolation structure, diode, or capacitor. The accompanying drawings show the substrate 100 in a plain rectangle in order to simplify the illustration. Suitable material for the bottom electrode 102, for example, is TaN, W, TiN, or TiW. Suitable material of the dielectric layer 105 is not limited and can be a silicon-containing compound, such as silicon nitride or silicon oxide. The heater 104 has a first profile width W1 of 200-5000 Å, such as 500-2000 Å. The heater 104 can be made of TaN, W, TiN, or TiW.

Next, referring to FIG. 3b, a part of the dielectric layer 105 is removed so that the top surface 121 of the heater 104 is outside of the top surface 122 of the dielectric layer 105 that is not removed, thereby defining an extended part 106 of the heater 104. The process for removing the first dielectric layer 105 comprises a wet etching or a dry etching process. Further, the method for removing the dielectric layer comprises a chemical mechanical polishing process.

Next, referring to FIG. 3c, the size of the extended part 106 of the heater 104 is decreased by an etching process 125 to form a smaller extended part 106a, wherein the top of the smaller extended part 106a has a second profile width W2 (less than the resolution limit of the photolithography process). Further, the smaller extended part 106a has a length L of 10-5000 Å, such as 50-4000 Å, 100-3000 Å, or 200-2000 Å. Referring to FIG. 3d, the second profile width can be 10-1000 Å, such as 100-600 Å. It should be noted that the heater has an etching rate exceeding that of the dielectric layer when the size of the extended part 106 of the heater is decreased by the etching process 125. In general, the etching rate of the heater is 50 times larger than that of the dielectric layer. The etching process comprises a wet etching or a dry etching process. Referring to FIG. 3d, the bottom 134 of the smaller extended part 106a can be lower than the top surface 122 of the first dielectric layer. Further, in another embodiment of the invention, the bottom 134 of the smaller extended part 106a can be higher than the top surface 122 of the first dielectric layer.

Next, referring to FIG. 3e, a dielectric layer 135 is formed to cover the smaller extended part 106a of the heater 104.

Next, referring to FIG. 3f, the dielectric layer 135 is subjected to a planarization process, exposing the top 130 of the smaller extended part 106a of the heater, wherein the planarization comprises a chemical mechanical polishing or an etching-back process. It should be noted that the top surface 136 of dielectric layer 135 is coplanar with the top surface of the top surface 130 of the smaller extended part 106a. Further, the top surface 130 of the smaller extended part 106a is higher than the top surface 136 of the dielectric layer 135.

Next, referring to FIG. 3g, a phase-change material layer 140 is formed on the dielectric layer 135, electrically connecting the phase-change material layer 140 and the top surface 130 of the smaller extended part 106a of the heater. The phase-change material layer 140 comprises chalcogenide such as In, Ge, Sb, Te or combinations thereof, for example GeSbTe or InGeSbTe.

Finally, referring to FIG. 3h, a top electrode 150 is formed and electrically connected on the phase-change material layer 140, thus, completing the process of the formation of a μ-trench phase-change memory element. The top electrode 150 can be the same as the first electrode 203 and can be metal or metal alloy, such as TaN, W, TiN, or TiW.

Accordingly, in the embodiments of the invention, the phase-change memory element has a heater with an extended part, wherein the extended part has a width less than the resolution limit of the photolithography process. The disclosed phase-change memory element allows reduction of both programming current and programming voltage, since the required Joule heating is reduced. Further, since the required programming current density is reduced, reliability is also enhanced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating phase-change memory elements, comprising:
forming a first dielectric layer with an opening on an electrode;
forming a heater within the opening to contact with the electrode, wherein the top surface of the heater is higher than that of the first dielectric layer, defining an extended part of the heater with a first width;
subjecting the first dielectric layer and the heater to an etching process to obtain an etched extended part of the heater, wherein the etched extended part has a second width less than the first width;
forming a second dielectric layer covering the etched extended part of the heater;
subjecting the second dielectric layer to a planarization process, exposing the extended part of the heater; and
forming a phase-change material layer on the second dielectric layer and directly in contact with the heater.

2. The method as claimed in claim 1, wherein the material of the phase-change material layer comprises chalcogenide.

3. The method as claimed in claim 1, wherein the second width is less than the resolution limit of the photolithography process.

4. The method as claimed in claim 1, wherein the method for forming the extended part of the heater comprises the following steps:
forming the heater within the opening; and
removing a part of the first dielectric layer, leaving the extended part outside of the top surface of the other part of the first dielectric layer that is not removed.

5. The method as claimed in claim 1, wherein the extended part has a length of 10-5000 Å.

6. The method as claimed in claim 1, wherein the second width is of 10-1000 Å.

7. The method as claimed in claim 1, wherein the heater has an etching rate exceeding that of the first dielectric layer.

8. The method as claimed in claim 1, wherein an etching rate of the heater is 50 times larger than that of the first dielectric layer.

9. The method as claimed in claim 1, wherein the etching process comprises a wet etching or a dry etching process.

10. The method as claimed in claim 1, wherein the planarization process comprises a chemical mechanical polishing process.

11. The method as claimed in claim 1, wherein the heater comprises an electrically connected material.

12. The method as claimed in claim 1, wherein the heater is made of TaN, W, TiN, or TiW.

13. A phase-change memory element, comprising:
an electrode;
a first dielectric layer formed on the electrode;
an opening passing through the first dielectric layer, exposing the electrode;
a heater formed in the opening to contact to the electrode, wherein the heater has an extended part outside of the opening;
a second dielectric layer surrounding the heater to expose the top surface of the extended part of the heater; and
a phase-change material layer formed on the second dielectric layer to directly contact to the top surface of the extended part of the heater.

14. The phase-change memory element as claimed in claim 13, wherein the material of the phase-change material layer comprises chalcogenide.

15. The phase-change memory element as claimed in claim 13, wherein the extended part has a length of 10-5000 Å.

16. The phase-change memory element as claimed in claim 13, wherein the top of the extended part has a width of 10-1000 Å.

17. The phase-change memory element as claimed in claim 13, wherein the heater is made of TaN, W, TiN, or TiW.

18. The phase-change memory element as claimed in claim 13, wherein the top surface of the extended part of the heater is coplanar with the top surface of the second dielectric layer.

19. The phase-change memory element as claimed in claim 13, wherein the top surface of the extended part of the heater is higher than the top surface of the second dielectric layer.

20. The phase-change memory element as claimed in claim 13, wherein the bottom of the extended part of the heater is lower than the top surface of the first dielectric layer.
